(19) United States
(12) Patent Application Publication
(10) Pub. No.: US 2010/0059310 A1
(43) Pub. Date: Mar. 11, 2010

(54) System and method for suppressing noise generated from a computer casing

(75) Inventors: A. Fred Hendrix, Salida, CA (US); Francisco Martinez-Ponce, Modesto, CA (US)

Correspondence Address: FOUNDRY-NIXON PEABODY LLP, P.O. Box 60610, Palo Alto, CA, 94306, US

(73) Assignee: Foundry Networks, Inc., a Delaware Corporation

(21) Appl. No.: 10/745,980

(22) Filed: Dec. 24, 2003

(51) Int. Cl. G10K 11/04; H05K 13/00

(52) U.S. Cl. 181/202; 29/592.1

(57) ABSTRACT

An enclosure containing and operating electronic equipment is envisioned. The enclosure alleviates sound energy emanating from the enclosure. The enclosure is made from a plurality of exterior walls. An aperture is disposed in one of the exterior walls, where the aperture is operable to draw an airflow into the enclosure. A structure is disposed adjacent to the aperture interior to the enclosure. The interior structure is made of a first wall disposed in the enclosure to block the aperture from a line of sight to a noise source emanating from within the enclosure. The interior structure also has a lower wall, an upper wall, and a side wall all connected to the first wall. The interior structure forms an open-ended cage about the aperture.

### FIELD OF THE INVENTION

The invention is directed towards a sound suppression system for a computer enclosure. More specifically, the invention is directed towards intake vents that suppress sound generated within an enclosure.

### BACKGROUND OF THE ART

Many computer systems have venting systems to allow a fan or other environmental mechanism to output heated air to an external environment. Typically, a fan will draw air from an external environment through intake vents disposed in the housing of the enclosure. This air is then drawn across electronic components found within the enclosure for the computer system. The heated electronic components transfer heat to the air as an airflow passes across the electronic components. A fan or other environmental outlet mechanism draws the heated air to an aperture or vent disposed in the enclosure. The fan then directs the heated air through the vent into the external environment.

In many systems, the sounds generated within the casing can be strong. These sounds can pass through the input vent essentially unimpeded. Accordingly, the sound of such systems can cause sonic discomfort to the users of the system.

### BRIEF DESCRIPTION OF INVENTION

An enclosure containing and operating electronic equipment is envisioned. The enclosure alleviates sound energy emanating from the enclosure. The enclosure is made from a plurality of exterior walls. An aperture is disposed in one of the exterior walls, where the aperture is operable to draw an airflow into the enclosure. A structure is disposed adjacent to the aperture interior to the enclosure. The interior structure is made of a first wall disposed in the enclosure to block the aperture from a line of sight to a noise source emanating from within the enclosure. The interior structure also has a lower wall, an upper wall, and a side wall all connected to the first wall. The interior structure forms an open-ended cage about the aperture.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is perspective view of an enclosure in accordance with the prior art.

FIG. 2 is a cutaway diagram of the enclosure of FIG. 1 detailing a sound dispersal structure disposed within the enclosure according to the invention.

FIG. 3 is a sectional view of an alternative embodiment of a sound reducing enclosure according to the invention.

FIG. 4 is a slice view from the top of the structure of FIG. 3 according to the invention.

FIG. 5 is a cutaway diagram of yet another alternative embodiment of a sound reducing enclosure according to the invention.

FIGS. 6a and 6b are planar cutaway diagrams detailing possible constructions of walls making up the interior structure according to the invention.

### DETAILED DESCRIPTION

Embodiments of a system and method for suppressing noise generated from a computer casing are described herein in the context of an enclosure for the storage and operation of electronic components. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another. Moreover, it will be appreciated that such a development effort might be complex and time-consuming, but would nevertheless be a routine undertaking of engineering for those of ordinary skill in the art having the benefit of this disclosure. In accordance with the present invention, the components or structures may be implemented using various types of items.

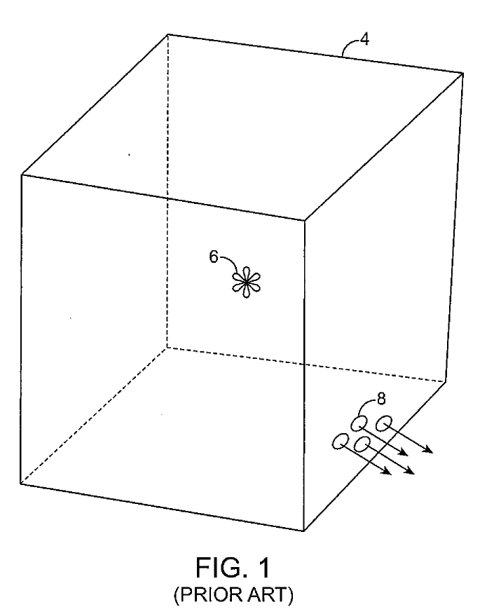

FIG. 1 is perspective view of an enclosure in accordance with the prior art. An enclosure 4 is made from several walls, including a top wall, a bottom wall, and side walls that connect them. The enclosure 4 is designed to house electronic components. The electronic components generate heat, and as such, need to be cooled. To effectuate this, a fan or other type of device that creates a flow of air is disposed within the enclosure 4. The fan or other type of device draws air from the external environment into the enclosure 4, and draws such air around the components to cool them.

In particular, air is drawn into the enclosure 4 through openings 8 in the walls of the enclosure 4. In many typical systems, the openings 8 allow the sounds from within the enclosure 4 to escape to the external environment.

The openings 8 typically allow a free path from noise produced by a noise source 6 disposed within the enclosure 4 to the external environment. Sound waves are pressure waves that travel in a compressional fashion through the air. The sounds produced from within the enclosure 4 typically include the sounds of fans and other such devices employed to circulate air within the enclosure 4 to alleviate heating within the enclosure 4. Thus, the pressure wavefronts emanating from within the enclosure 4 may be dispersed through any openings in the enclosure 4. Thus, sounds corresponding to operating the electronic devices within the enclosure 4 are free to escape into the environment surrounding the enclosure 4, and cause annoyance and possible disruption of work being performed in the area.

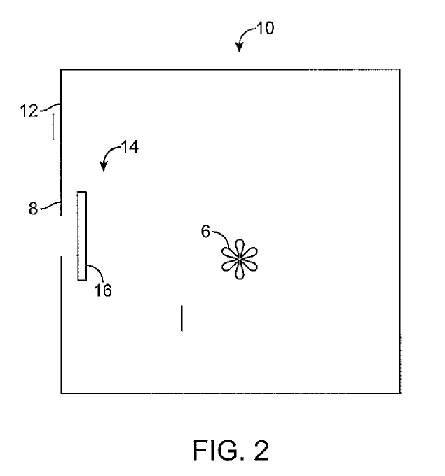

FIG. 2 is a cutaway diagram of the enclosure of FIG. 1 detailing a sound dispersal structure disposed within the enclosure according to the invention. FIG. 2 is a cutaway diagram of the enclosure 10 through a plane running parallel to a top of the enclosure 10. The side wall 12 contains several openings 8 to allow an airflow through the enclosure 10. Disposed within the enclosure 10 is an internal mechanism 6 producing sound waves. Coupled to the side wall 12 and disposed generally about the opening 8 is a structure 14. The structure 14 contains a back wall 16 that shields the opening 8 from the noise source(s) 6 disposed inside the enclosure 10. Pressure waves emanating from the noise source impinge upon the back wall 16 and either diffract around the back wall 16 or are reflected back into the interior of the enclosure 10.

Noise energy containing components at higher frequencies tend not to diffract around line of sight obstacles, such as the structure 14 or the back wall 16. Thus, the higher frequency components mainly are directed away from the openings 8 present in the wall 12 of the enclosure 10.

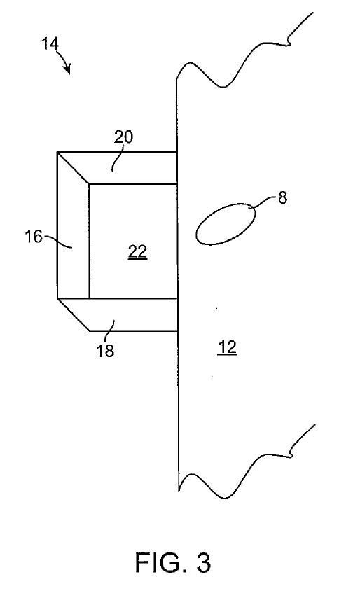

FIG. 3 is a sectional view of an alternative embodiment of a sound reducing enclosure according to the invention. In this aspect, a top wall 20, a bottom wall 18, and a side wall 22 supplement the back wall 16. In this aspect of the invention, the structure 14 forms a baffle about the opening 8 present in the exterior side wall 12.

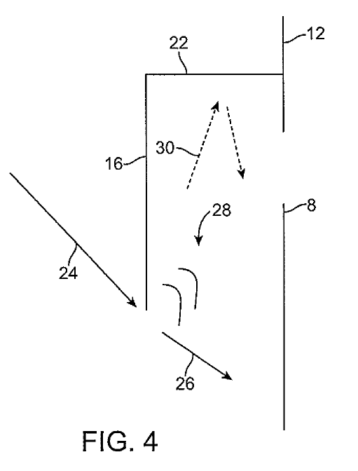

FIG. 4 is a slice view from the top of the structure of FIG. 3 according to the invention. FIG. 4 shows the wave paths from the sound source are cut off from the opening 8 by the structure 14. High frequency components are highly directional, and as such, do not diffract easily around the structure 14. Thus, high frequency component of sound emanating from the interior of the enclosure is impinged dramatically by the structure 14 disposed about the opening 8. Additional noise abatement may also be effected on lower frequency components as well, since the sound waves that tend to diffract around the structure 14 will tend to interfere with reflections emanating off the wall 22 of the structure.

In particular noise generated within the enclosure is represented by an arrow 24. High frequency components are directional, and do not diffract around the wall 16. Thus, they are represented as the arrow 26, which indicates that the high frequency portions do not escape from within the enclosure through the opening 8.

Lower frequency components are not directional, and can diffract around the wall 16. Thus, they are represented as the waves 28. A portion of this sound energy is directed onto the wall 22, from where they are reflected back into the plenum formed by the exterior wall 12, and the wall 16, the wall 22, and the top and bottom portions of the cage-like structure that is disposed about the opening 8. These reflected waves then interfere with the newly diffracted waves.

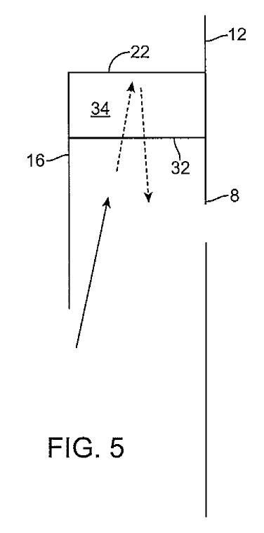

FIG. 5 is a cutaway diagram of yet another alternative embodiment of a sound reducing enclosure according to the invention. In this aspect of the invention, a structure is formed about the airways, and this structure serves a dual function. In addition to the line of site abatement shown in the examples previously described, the shape of the structure may be formed to make a sonic reflector or resonator. For example, an inner wall 32 may be disposed within the inner volume or plenum defined by the structure 14 described previously. The inner wall 32 can be formed with an aperture in it.

The combination of the inner wall 32 with the rest of the structure produces a back wave emanating out of a chamber 34 defined by the back wall 22, the inner wall 32, the wall 16, the top and bottom walls, and the exterior wall 12. This backwave then exits the aperture in the inner wall 32 and meets the now oncoming sound waves. The volume and dimensions of the chamber 34 may be designed to provide a reflective-type muffler for incoming sound waves to the structure. In this manner, further abatement may be obtained from the structure.

FIG. 5 may be used to demonstrate the muffler effect of the structure depicted therein. A sound wave emanates at the entrance of the structure. This may be a diffracted wave from the edge of the structure, or reflected sound from another interior surface of the enclosure. The sound wave comes to the entrance of the inner wall 32, and the aperture in the inner wall 32 provides a point source for sound to emanate into the chamber 34. The sound wave in the chamber 34 is reflected off the inner surfaces of the chamber 34. The chamber's volume and dimensions are “tuned” to produce a reflected inverted wave at the aperture in the inner wall 32 making up the chamber 34 for a particular frequency. The now inverted sound wave now interferes destructively with the any new incoming sound waves, thus abating the noise emanating from the aperture 8.

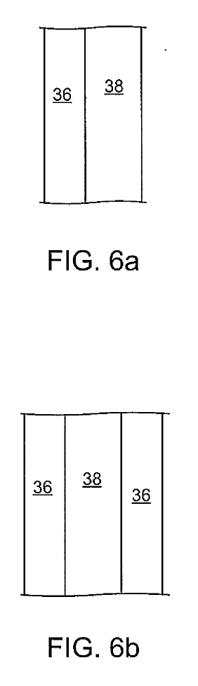

FIGS. 6a and 6b are diagrams detailing possible constructions of walls making up the interior structure according to the invention. The interior structure may be made of two or more differing materials.

First, a rigid material having a fairly heavy weight makes up a first portion 36 of the wall. A second portion 38 of the wall is made of a sound absorptive layer. In this manner, the construction and composition of the wall allows further sound suppressive effects to occur. Energy in sound waves striking the absorptive layer 38 may end up with three different outcomes. First, the sound may be reflected. For highly sound absorbent material, very little of the impinging sound is reflected. In a second outcome, the absorptive material 38 absorbs some of the energy associated with the sound wave. The remaining energy in the impinging sound wave is transmitted.

Turning now to the effect of the first portion 36 on sound wave energy, most sound energy striking the first portion 36 is mainly reflected. Thus, very little energy in the wall is transmitted outwards. Typically, the mass of the first portion 36 tends to attenuate transmission. On the “return, outward bound” trip, again some of the sound is absorbed by the absorptive material making up the second portion 38.

Walls of this type may be used both on the inner and outer portions of the structures described above relative to FIGS. 1-4. In particular, a triple layer wall, such as that shown in FIG. 6b, can work acoustic effects on sound within the enclosure and sound energy leaving the enclosure through the exterior aperture. In this case, the non-transmissive layer is sandwiched between two layers of absorptive layers, providing acoustic abatement for sound waves on both sides. In this case, both sound waves striking the outward facing surfaces and those that are diffracted into the exit plenum are attenuated prior to their exit from the enclosure through interaction with the walls making up the plenum.

Thus, a system and method for suppressing noise generated from a computer casing is described and illustrated. Those skilled in the art will recognize that many modifications and variations of the present invention are possible without departing from the invention. Of course, the various features depicted in each of the figures and the accompanying text may be combined together. Accordingly, it should be clearly understood that the present invention is not intended to be limited by the particular features specifically described and illustrated in the drawings, but the concept of the present invention is to be measured by the scope of the appended claims. It should be understood that various changes, substitutions, and alterations could be made hereto without departing from the spirit and scope of the invention as described by the appended claims that follow.

1. An enclosure containing and operating electronic equipment, the enclosure comprising:
one or more exterior walls;
an airflow aperture disposed in one of the exterior walls, the aperture operable to allow an external environment to interact with an internal environment of the enclosure; and
a structure disposed adjacent to the aperture, the structure operable to block all lines of sight between the aperture and a noise source disposed within the enclosure, the structure comprising a plurality of walls, at least two of the plurality of walls coupled to the one of the exterior walls, at least a portion of the structure comprising:
a first layer comprised of a sound transmission resistant material; and
a second layer comprised of a sound absorbing material.

2. The enclosure of claim 1 wherein the structure is mounted to the one of the exterior walls.

3. The enclosure of claim 1 wherein the aperture comprises a group of apertures disposed on an area of the one of the walls; and
the structure disposed within the enclosure to block the area from a line of sight to the noise source disposed within the structure.

4. (canceled)

5. (canceled)

6. The enclosure of claim 1 wherein the first layer is disposed on a side of the structure facing the aperture.

7. The enclosure of claim 6 wherein the second layer is disposed on a side of the structure facing away from the aperture.

8. The enclosure of claim 7 wherein the structure further comprises:
a third layer comprised of a sound absorbing material, wherein the first layer is disposed between the third layer and the second layer.

9. The enclosure of claim 1 wherein the structure further comprises: a first, second, and third walls; and
wherein the first, second, and third walls are connected to the structure to form an inner open enclosure disposed about the aperture.

10-13. (canceled)

14. A method of making an enclosure operable to diminish noise emanating from within the enclosure, the method comprising:
forming an enclosure having a first wall, a second wall, a third wall, a fourth wall, and a fifth wall, the first wall, second wall, third wall, fourth wall, and fifth wall forming a volume to store and operate electronic components;
forming an exterior aperture disposed on an exterior wall, the exterior wall being one of the first, second, third, fourth, or fifth walls;
forming an interior structure about the aperture, the structure operable to block all lines of sight between the aperture and a noise source disposed within the enclosure, the aperture operable to diminish sound emanating from the interior of the enclosure, the interior structure comprising a plurality of walls, at least two of the plurality of walls coupled to one of the first, second, third, fourth, or fifth walls, at least a portion of the structure comprising:
a first layer comprised of a sound transmission resistant material; and
a second layer comprised of a sound absorbing material.

15. The method of claim 14, wherein the step of forming the interior structure comprises:
forming an open ended passage about the aperture, the open end of the passage directed away from central portion of the interior volume.

16. The method of claim 15, wherein the step of forming the interior structure further comprises:
placing an interior wall within the enclosure to block the aperture from a line of sight to a noise source emanating from within the enclosure;
connecting a lower wall to the interior wall and to the exterior wall; connecting an upper wall to the interior wall and to the exterior wall;
connecting a side wall to the interior wall, the lower wall, and the upper wall.

17-18. (canceled)
